(19) United States
(12) Patent Application Publication
(10) Pub. No.: US 2011/0114171 A1
(43) Pub. Date: May 19, 2011

(54) SOLAR CELL INCLUDING SPUTTERED REFLECTIVE LAYER

(75) Inventors: Daniel L. Meier, Norcross, GA (US); Vinodh Chandrasekaran, Suwanee, GA (US); Bruce McPherson, Acworth, GA (US)

(73) Assignee: SUNIVA, INC.

(21) Appl. No.: 13/014,352

(22) Filed: Jan. 26, 2011

Related U.S. Application Data
(62) Division of application No. 12/684,682, filed on Jan. 8, 2010.

(51) Int. Cl. H01L 31/0264; H01L 31/0216; H01L 31/0236; H01L 31/04; H01L 31/036; H01L 31/0368; H01L 31/18

(52) U.S. Cl. 136/256; 136/258; 136/261; 438/72; 257/E31.119

(57) ABSTRACT

Solar cells and methods for their manufacture are disclosed. An exemplary method may include providing a semiconductor substrate and introducing dopant atoms to a front surface of the substrate. The substrate may be annealed to drive the dopant atoms deeper in the substrate to produce a p-n junction while also forming front and back passivation layers. A reflective surface is sputtered on the back surface of the solar cell. It protects and generates hydrogen to passivate one or more substrate-passivation layer interfaces at the same time as forming an anti-reflective layer on the front surface of the substrate. Fire-through of front and back contacts as well as metallization with contact connections may be performed in a single co-firing operation. Associated solar cells are also provided.

### CROSS-REFERENCE TO RELATED APPLICATIONS

This application is a divisional of co-pending U.S. application Ser. No. 12/684,682, filed Jan. 8, 2010, which is hereby incorporated herein in its entirety by reference.

### TECHNOLOGICAL FIELD

The present invention is generally directed to a solar cell having a back reflective surface, and methods for its manufacture. The reflective surface directs light reaching the back surface of the solar cell back into the semiconductor substrate where it can be absorbed again to produce charge carriers to produce electric energy.

### BACKGROUND

In basic design, a solar cell is composed of a material such as a semiconductor that absorbs energy from photons to generate free charge carriers (electrons and holes) through the photovoltaic effect. The semiconductor material is doped with p-type and n-type impurities to create an electric field inside of the solar cell. This electric field sorts and directs free electrons and holes to opposite contacts of the solar cell. Through electrical connections, the solar cell can supply the charge carriers to power a load.

The amount of incident light the solar cell is able to convert to electric power is termed its ‘conversion efficiency’ and it is a very important metric to evaluating the quality of a solar cell. In general, the more efficient the solar cell, the fewer are needed in a panel to produce a given amount of electric power. Therefore, panel manufacturers and end users of solar cells generally demand ever more efficient solar cells produced at lower cost.

Silicon substrates have been used at the core of solar cell devices for many years, and they remain a dominant component in many solar cell architectures currently in use throughout the world. Silicon substrates offer several advantages. The basic element, silicon, is plentiful and highly pure sources of it are easily accessible at the surface of the earth. It can therefore be readily mined and processed, which contributes to lowering its cost. Furthermore, silicon is a safe material and generally poses no serious environmental concerns or health risks to those exposed to it.

Moreover, silicon has proven to be a very reliable substrate for a solar cell, having a useful lifetime from 25 to 35 years or more. Thus, silicon is an attractive choice for use as a solar cell material.

With increasing demand for silicon substrates in both the solar and electronics industries, the price of silicon has increased in recent years, spawning interest in other ways to reduce the cost of a solar cell. Alternatives to silicon, such as ‘thin-film’ technologies, are under investigation. Cadmium indium selenide (CIS) or cadmium indium gallium selenide (CIGS), or polymeric solar cell devices, are currently being explored as possible substitutes for silicon. However, these alternatives have not been developed to the point of ubiquity, and many of these alternatives have been discounted as not expected to be viable technologies for the foreseeable future. Nonetheless, these alternative approaches have provided a degree of competition for silicon, and they have thus helped to increase interest in ways to reduce the cost of silicon-based solar cell devices.

The most common silicon-based solar cell technologies use crystalline silicon (c-Si) or multi-crystalline silicon (m-Si) substrates. Crystalline silicon is usually produced through Czochralski (Cz) or float zone (FZ) techniques, which are relatively expensive processes because of the amount of energy required to melt silicon to produce a crystal boule. Sawing the boule and polishing the resulting wafers to produce substrates suitable for solar cells also contributes to the cost. In contrast, multicrystalline silicon can be formed by casting, which produces a lower-cost substrate, but one that is subject to recombination of charge carriers at the crystal grain boundaries if techniques are not employed to passivate them. String ribbon silicon substrates are also in production, as are some silicon thin-film technologies.

One of the challenges in producing lower-cost crystalline silicon solar cells is to reduce the amount of silicon used in their manufacture because the silicon substrate itself constitutes a major portion of the cost of producing a solar cell. This can be done by decreasing the thickness of the silicon substrate. However, as the thickness of the silicon substrate is reduced, an increasing amount of solar energy is not absorbed but instead passes entirely through the back surface of the substrate. This is especially true of light at the longer wavelengths on the red and infrared side of the spectrum, which requires a greater distance of travel in the silicon to be absorbed. One approach to addressing this problem is to provide a reflective surface on the back of the solar cell. Light energy passing through the solar cell on the first pass reflects from the reflective surface and passes back into the solar cell, providing another opportunity for it to be absorbed in the silicon substrate to produce free charge carriers for electric power.

One disadvantage of current approaches to forming back reflective surfaces in solar cells is that the reflective material is usually a metal, and direct contact of metal against a semiconductor substrate creates a recombination zone which annihilates charge carriers before they can be collected at the contacts to provide electric power to a load. To avoid this, a dielectric layer of silicon dioxide or silicon nitride is used over the back surface to separate the metal layer from the semiconductor substrate over most of its area except where local point or line contacts are formed to make electrical connection to the substrate. However, after depositing the dielectric layer, the inventors have discovered that subsequent thermal cycles necessary for the manufacture of a solar cell degrade the substrate-dielectric boundary, causing it to be a significant source of recombination of charge carriers, which drives down the efficiency of the resulting solar cell.

Another disadvantage of current approaches to forming back reflective surfaces for solar cells is that they have comparatively low throughput, thereby contributing significantly to the cost of a solar cell. For example, techniques such as chemical vapor deposition (CVD) or evaporation require a significant amount of time in order to deposit metal of sufficient thickness to produce a reflective back surface. The longer time of manufacture of the reflective surface contributes directly to the cost of the resulting solar cell. It would be desirable to overcome this disadvantage of previous manufacturing methods.

In addition, the inventors have recognized that previous manufacturing processes to produce solar cells with reflective surfaces suffer the disadvantage of requiring numerous steps. Not only do these numerous steps increase the complexity of the process, they require additional time and equipment, and therefore expense, to produce solar cells. Because a solar cell manufacturer's cost of manufacture and profitability are directly tied to throughput, it would be desirable to overcome these disadvantages of previous approaches.

Thus, there is a need in the art for solar cells with reflective back surfaces and methods for their manufacture that overcome the above-mentioned and other disadvantages and deficiencies of previous technologies.

### BRIEF SUMMARY OF SOME EXAMPLES OF THE INVENTION

Various embodiments of a silicon solar cell with reflective back surface and methods for its manufacture are herein disclosed. These embodiments of the invention overcome one or more of the above-described disadvantages associated with previous technologies. Embodiments of the invention provide several advantages for production of solar cells that reduce the time and cost required for their production.

A solar cell according to an exemplary embodiment of the invention comprises a semiconductor substrate composed of silicon (Si), germanium (Ge) or silicon-germanium (SiGe) or other semiconductive material. The substrate has a front region containing dopant atoms of a first conductivity type, and a back region containing dopant atoms of a second conductivity type opposite to the first conductivity type. The substrate defines a p-n junction at the interface between the front region and the back region. A front passivation layer including a dielectric such as silicon dioxide (SiO₂) is situated on the front surface of the substrate. A back passivation layer which may include silicon dioxide (SiO₂) is situated on the back surface of the silicon substrate. An anti-reflective layer including silicon nitride (Si₃N₄), aluminum oxide (Al₂O₃), titanium oxide (TiO₂), magnesium fluoride (Mg₂F), or zinc sulfide (ZnS₂), or combinations of these materials, is situated on the front passivation layer. A sputtered reflective layer including aluminum (Al) or other metal or metal alloy is situated on the back passivation layer. Front contacts are arranged at spaced locations on the front surface of the solar cell and configured to extend through the antireflective layer and front passivation layer to connect with the front region of the substrate. Back contacts are arranged at spaced locations on the back surface of the solar cell and configured to extend through the reflective layer and the back passivation layer to connect with the back region of the substrate. Front and back connections make contact with respective front and back contacts. The interfaces between the front passivation layer and the silicon substrate and the back passivation layer and the silicon substrate contain hydrogen to passivate and lower density of interface states.

According to another exemplary embodiment of the invention, a method is disclosed for manufacturing a solar cell having a reflective back surface. As the starting material for the method, a semiconductive substrate such as a wafer can be used. The method may commence by texturizing the front and back surfaces of a semiconductor substrate through anisotropic etching with an alkaline or acidic solution to form anti-reflective pyramidal structures on its front surface and back surfaces. The pyramidal structures cause incident light to enter and remain within the substrate as opposed to being reflected from its surfaces.

The method comprises introducing dopant atoms of opposite conductivity to the substrate to its front surface. This introducing step can be carried out using a variety of techniques, including gas diffusion, ion implantation, spin-on source or a starved source. Any surface glass resulting from the introduction of dopant atoms can be removed through a glass etch using hydrofluoric (HF) acid. However, use of ion implantation, spin-on or starved source techniques can be used to control the amount of dopant atoms introduced to avoid the formation of glass at the front surface of the substrate, thereby eliminating the need for a step to remove it.

The method also comprises forming front and back passivation layers on a silicon substrate. This can be done by subjecting the substrate to an elevated temperature in a furnace with an oxygen-containing atmosphere. As a result of the heating in an oxygen atmosphere at a sufficiently high temperature, passivation layers composed of silicon dioxide (SiO₂) (or other oxide for non-silicon substrates) form on respective front and back surfaces of the substrate. Advantageously, the diffusion of the dopant atoms and annealing to activate the solar cell's p-n junction can be performed simultaneously with the formation of the front and back passivation layers. This reduces the number of steps required to manufacture the solar cell.

The method of this embodiment further comprises a step of sputtering metal onto the back passivation layer to form a reflective layer. The metal can be aluminum (Al), for example. Sputtering is a technique which can be conducted relatively quickly, thereby improving throughput as compared to other techniques. Also, due to the reflective layer formed through this sputtering step, the substrate may be made less thick than otherwise required to absorb most of the light incident to the solar cell's front surface. This permits less substrate material to be used in the solar cell, thereby lowering its cost. The sputtered reflective layer also protects the interfaces between the substrate and the passivation layers in subsequent processing steps, lowering the density of interface states and recombination rates of charge carriers at these interfaces. Thus, the reflective surface can be useful for multiple purposes.

The method of this embodiment also comprises forming an antireflective layer such as silicon nitride (Si₃N₄), aluminum oxide (Al₂O₃), titanium oxide (TiO₂), magnesium fluoride (Mg₂F), zinc oxide (ZnO), or zinc sulfide (ZnS₂), on the front passivation layer. The antireflective layer can be formed through a technique such as plasma-enhanced chemical vapor deposition (PECVD) at a temperature sufficiently elevated to cause the reflective layer to absorb thermal energy. The heated reflective layer reduces water vapor present in at least the back surface of the silicon substrate. This reduction produces hydrogen to passivate the interface between the back passivation layer and the substrate. The water vapor is present at the interfaces between the passivation layers and the substrate is due to ambient humidity within the manufacturing facility. Most manufacturing facilities (known as Tabs') are maintained at a humidity between 40-60%, which is sufficient to cause water vapor to infiltrate the substrate-passivation layer interfaces. Thus, the reflective layer serves yet another role in passivating the interfaces between the passivation layers and substrate during formation of the anti-reflective layer.

The method can comprise applying front and back contacts to the antireflective and reflective layers, respectively. In addition, connections such as grid lines, bus bars and tabs are formed on the front and back surfaces of the solar cell to make contact with respective front and back contacts. The method can also comprise co-firing the front and back contacts and front and back connections so that the front contacts fire through the front antireflective layer and the front passivation layer to make connection to the front surface of the silicon substrate. Also, the co-firing causes the back contacts fire through the reflective layer and back passivation layer to make connection with the back surface of the silicon substrate. Through the co-firing, respective front and back contacts and front and back connections are sintered or melted together to provide electrical connection to the solar cell via the front and back connections. Thus, in one step, the solar cell contacts and connections can be formed and annealed to produce a solar cell with excellent efficiency. In addition, the reflective layer protects the interfaces between the back passivation layer, and possibly also the front passivation layer, and the substrate, to prevent interface degradation leading to charge carrier recombination with resulting loss of efficiency.

The applying of the front contacts can be accomplished by printing dots of fitted silver paste at front contact locations. The frit causes the silver paste to fire-through the antireflective and front passivation layers to make contact to the substrate. The silver paste used to make the front connections can be fritless so that the connection does not fire-through but remains on the surface of the antireflective layer. The back contacts can be formed by printing dots of fitted aluminum paste at back contact locations, which fires-through the reflective layer and passivation layer to make contact with the substrate's back surface. The back connections can be applied by printing a fritless silver paste on the back surface of the solar cell to connect to the back contacts.

Another exemplary embodiment of the invention is directed to a solar cell with back reflective surface formed with the above-identified method.

The above summary is provided merely for purposes of summarizing some exemplary embodiments of the invention so as to provide a basic understanding of some aspects of the invention. Accordingly, it will be appreciated that the above described exemplary embodiments and should not be construed to narrow the scope or spirit of the invention in any way more restrictive than as defined by the specification and appended claims. It will be appreciated that the scope of the invention encompasses many potential embodiments, some of which will be further described below, in addition to those here summarized.

### BRIEF DESCRIPTION OF THE DRAWING(S)

Having thus described embodiments of the invention in general terms, reference will now be made to the accompanying drawings, which are not necessarily drawn to scale, and wherein:

FIG. 1 illustrates a cross-sectional view of a solar cell in accordance with an exemplary embodiment of the present invention; and

FIG. 2 (including FIGS. 2a, 2b, and 2c) illustrates a flowchart according to an exemplary embodiment of a method for manufacturing a solar cell with respective illustrations of the construction of the solar cell apparatus and the operations performed in the exemplary method.

### DETAILED DESCRIPTION

Some embodiments of the present invention will now be described more fully hereinafter with reference to the accompanying drawings, in which some, but not all embodiments of the invention are shown. Those skilled in this art will understand that the invention may be embodied in many different forms and should not be construed as limited to the embodiments set forth herein; rather, these embodiments are provided so that this disclosure will satisfy applicable legal requirements. Like reference numerals refer to like elements throughout.

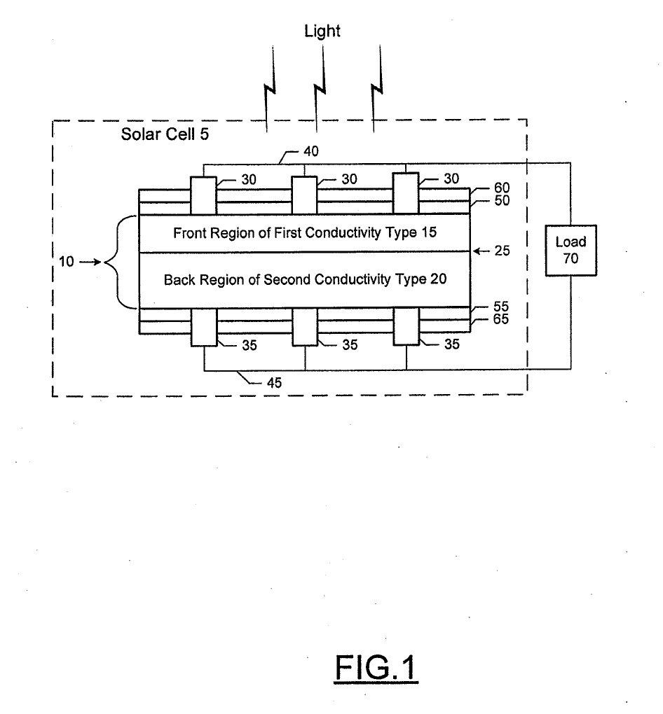

FIG. 1 illustrates one embodiment of a solar cell 5 in accordance with the present invention. The solar cell 5 may be formed on a semiconductor substrate 10. The substrate 10 may be composed of silicon (Si), germanium (Ge) or silicon-germanium (SiGe) or other semiconductive material, or it may be a combination of such materials. In the case of monocrystalline substrates, the semiconductor substrate 10 may be grown from a melt using Float Zone (FZ) or Czochralski (Cz) techniques. The resulting mono-crystalline boule may then be sawn into a wafer which is polished to form the substrate 10. For a substrate composed of silicon, germanium or silicon-germanium, the crystallographic orientation may be (100) or (110), for example. Alternatively, the substrate 10 can be multi-crystalline. In the typical case, the multi-crystalline substrate is cast in a mold in the form of a wafer. The molding avoids the need to saw wafers, and also the resulting kerf loss. However, the multi-crystalline substrate suffers from recombination of charge carriers at crystal grain boundaries, and requires passivation to avoid efficiency losses.

The resistivity of the substrate 10 can be in the range from one to one-hundred (1-100) Ohm-centimeter (Ω-cm). Within this range, the inventors have determined that, for a silicon substrate, a resistivity of from one to three (1-3) Ω-cm yields excellent results. The thickness of the substrate 10 can be from 100 to 200 millimeters (mm) square or pseudosquare with a thickness of 50 to 500 micrometers (μm). However, a wafer thickness in a range from 50 to less than 200 μm is possible, thereby significantly reducing the amount of material used relative to current standards for substrates. The substrate 10 may be doped with dopant atoms to provide a particular conductivity. For silicon, germanium or silicon-germanium substrate, a p-type dopant such as boron (B), gallium (Ga), indium (In), aluminum (Al) or possibly another Group III element may be used. Phosphorus (P), antimony (Sb), arsenic (As) or possibly another Group V element can be used as an n-type dopant. The dopant concentration may be in a range from 10¹⁵ to 10²¹ atoms per cubic centimeter (atoms/cm³). Those of ordinary skill in the art understand that numerous kinds of semiconductor substrates and dopant species may be used without departing from the scope of the disclosed invention. Exemplary substrates are commercially available from numerous sources including Shin-Etsu Handotai Corporation of Japan, and Renewable Energy Corporation (REC) ASA of Norway.

According to the exemplary embodiment of FIG. 1, the solar cell 5 comprises a front region 15 with a first conductivity type (p-type or n-type) and a back region 20 with a second conductivity type (n-type or p-type) opposite to that of the first region 15. The two regions 15, 20 physically contact to form a p-n junction 25. Because of their opposite conductivities, the regions 15, 20 create an electric field across the p-n junction 25 which separates free electrons and holes resulting from absorption of light energy and forces them to move in opposite directions to respective front and back contacts 30, 35. The front and back contacts 30, 35 are formed of a eutectic composition of conductive material such as silver (Ag) or aluminum (Al) and the underlying semiconductor substrate. Generally, for silicon and other substrates, silver is used to contact the one of the regions 15, 20 that is n-type, and aluminum or silver is used to contact the other of the regions 15, 20 that is p-type. The contacts 30, 35 are thus composed of a silver-silicon or aluminum-silicon eutectic composition. Direct contact of metal to semiconductor increases the recombination rate of electrons and holes, which can significantly lower solar cell efficiency. The contacts 30, 35 may be configured as point or line contacts (sometimes called ‘local contacts’) to limit the contact of metal on the semiconductor substrate 10. The spacing and arrangement of point or line contacts can be determined as described in U.S. Publication No. 2009/0025786 published Jan. 29, 2009, which is incorporated by reference as if set forth in full herein. In addition, for the front contacts 30, silver may be selected to limit shadowing effects which can lower solar cell efficiency. However, silver is not transparent, so it may be desirable to limit the dimensions of the front contacts 30 to point or line contacts of limited area for this additional reason. It is also possible to use relatively heavy doping under the contacts 30, 35 in order to reduce contact resistance. For this purpose, a self-doping paste may be used to form the contacts 30, 35. The self-doping paste and other techniques for producing heavy doping under a contact are disclosed in U.S. Pat. Nos. 6,180,869, 6,632,730, 6,664,631, 6,703,295 and 6,737,340, all of which are incorporated herein by reference as if set forth in full herein.

The front and back surfaces of the substrate 10 define pyramidal structures created by their treatment with a solution of potassium hydroxide (KOH) and isopropyl alcohol (IPA). The presence of these structures increases the amount of light entering the solar cell by preventing light from reflecting from the front surface. At the back surface, the pyramidal structures perform a similar function in connection with a reflective surface to be described later in this specification.

The front and back surfaces of the semiconductor substrate 10 represent a discontinuity in its crystalline structure, and dangling bonds are present at these exposed surfaces. The dangling bonds constitute recombination centers which disadvantageously annihilate charge carriers, thus lowering the efficiency of the solar cell. To prevent this from occurring, passivation layers 50, 55 are formed on opposite sides of the substrate 10 in contact with respective front and back regions 15, 20 of the semiconductor substrate 10. The passivation layers 50, 55 contact respective front and back regions 15, 20 of the substrate 10 in order to chemically satisfy the bonds of the substrate atoms at these interfaces so that they will not annihilate charge carriers. The passivation layers 50, 55 may comprise a dielectric material such as silicon dioxide (SiO₂) for a silicon substrate 10, or an oxide of another semiconductor type, depending upon the composition of the substrate 10. Each of the passivation layers 50, 55 may have a thickness in a range from 10 to 100 nanometers. For example, 20 nanometers may be used. In accordance with some exemplary embodiments, the passivation layers 50, 55 may be disposed on the surfaces of respective front and back regions 15, 20 prior to forming the back contacts 40. In this case, the front and back contacts 30, 35 physically penetrate respective passivation layers 50, 55 to make contact with respective front and back regions 15, 20 of the semiconductor substrate 10. The front and back contacts 30, 35 may contain glass frit in addition to metal to facilitate their firing through the passivation layers 50, 55 to make contact with the substrate 10.

To increase the amount of light entering the substrate 10, an anti-reflective layer 60 can be used. The anti-reflective layer 60 has a refractive index greater than that of the front passivation layer 50, which tends to cause light incident to the solar cell to refract into the anti-reflective layer 60 and through the passivation layer 50 to the substrate 10 where it can be converted to free charge carriers. The anti-reflective layer 60 can be composed of silicon nitride (Si₃N₄), aluminum oxide (Al₂O₃), titanium oxide (TiO₂), magnesium fluoride (Mg₂F), zinc oxide (ZnO), or zinc sulfide (ZnS₂), or combinations of these materials. Exemplary thickness of the anti-reflective layer 60 can be from 10 to 100 nanometers (nm). The front contacts 30 extend through the anti-reflective layer 60 as well as the front passivation layer 50 to make contact with the front region 15.

As previously mentioned, the solar cell 5 comprises a reflective layer 55. For example, aluminum may be sputtered on the back surface of the solar cell 5 to form the reflective layer 55. The reflective layer 55 covers exposed portions the passivation layer 55, and possibly also the back region 20 if contact holes are present in advance of sputtering. The reflective layer 65, in combination with the dielectric passivation layer 55, provides a reflective surface to return incident light reaching it back to the substrate 10 where it can generate free charge carriers. The thickness of the reflective layer 55 can be from 0.2 to 1.0 micrometer in thickness to provide sufficient reflectivity.

The reflective layer 55 serves other important purposes in the solar cell 5. Namely, it serves as a protective coating to prevent degradation of the back substrate-passivation layer interface, during one or more thermal cycles required to manufacture the solar cell. In addition, the reflective layer 55 absorbs heat which reduces water vapor natively present at the interfaces between the substrate 10 and the passivation layers 50, 55 because of humidity present in the manufacturing facility. Hydrogen is thereby produced, which has a passivating effect at the substrate-passivation layer interface. Hydrogen satisfies dangling bonds and other crystalline defects at such interface which could lead to increased recombination rates for the charge carriers.

The reflective layer 55 may be formed by a sputtering technique. Sputtering refers to a process for depositing thin films onto a surface by using an ionized gas molecule to displace atoms of a specific material, such as aluminum. The displaced atoms bond to the surface and create a film. Several types of sputtering processes may be used in accordance with exemplary embodiments of the present invention, such as ion beam sputtering, diode sputtering, and magnetron sputtering. Sputtering can provide uniformity for the reflective layer 55 with enhanced throughput in its manufacture. The reflective layer 55 has characteristics which reflect its origination, namely, a film may be created that appears to be highly metallic and very reflective unlike other techniques, such as, for example, like screen printing.

The front and back contacts 30, 35 are electrically connected to respective connections 40, 45 on the front and back surfaces of the solar cell 5. The connections 40, 45 can be conductive traces or wires or other connections which deliver electric power to load 70. Silver can be advantageously used for the front connections 40. To limit shadowing, the front connections 40 may be disposed in a grid pattern (e.g., as grid lines and bus bars), thereby having areas where light may enter the solar cell 5 unimpeded by the connections 40. The connections 40, 45 can be connected to the load 70 to provide electric power to it in response to the solar cell's conversion of light energy into electric energy.

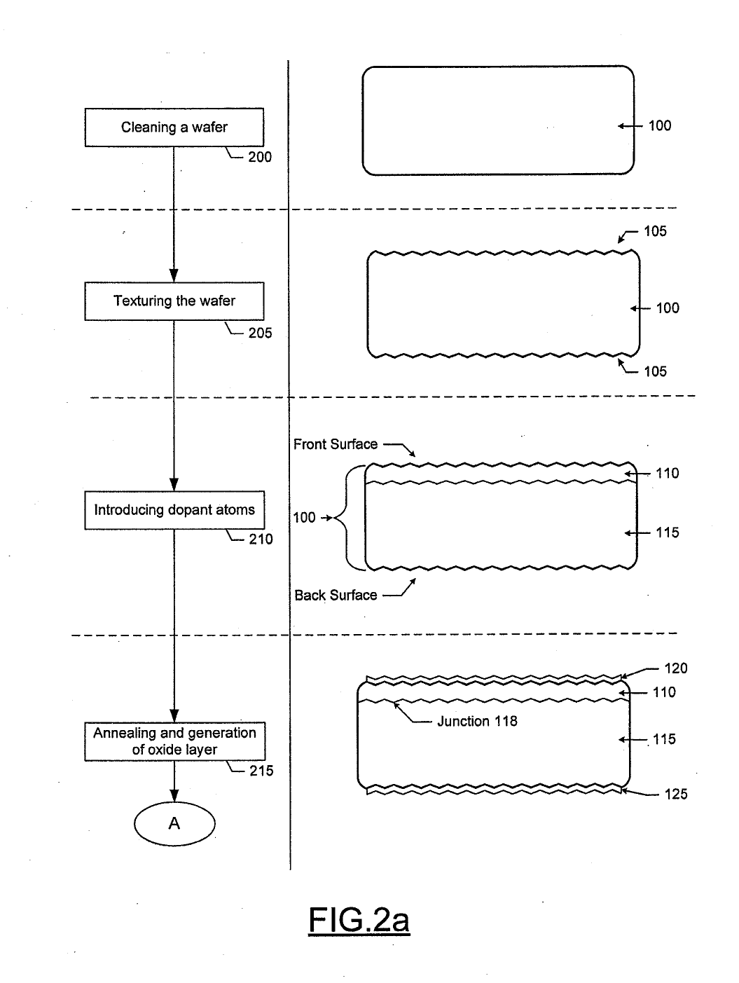

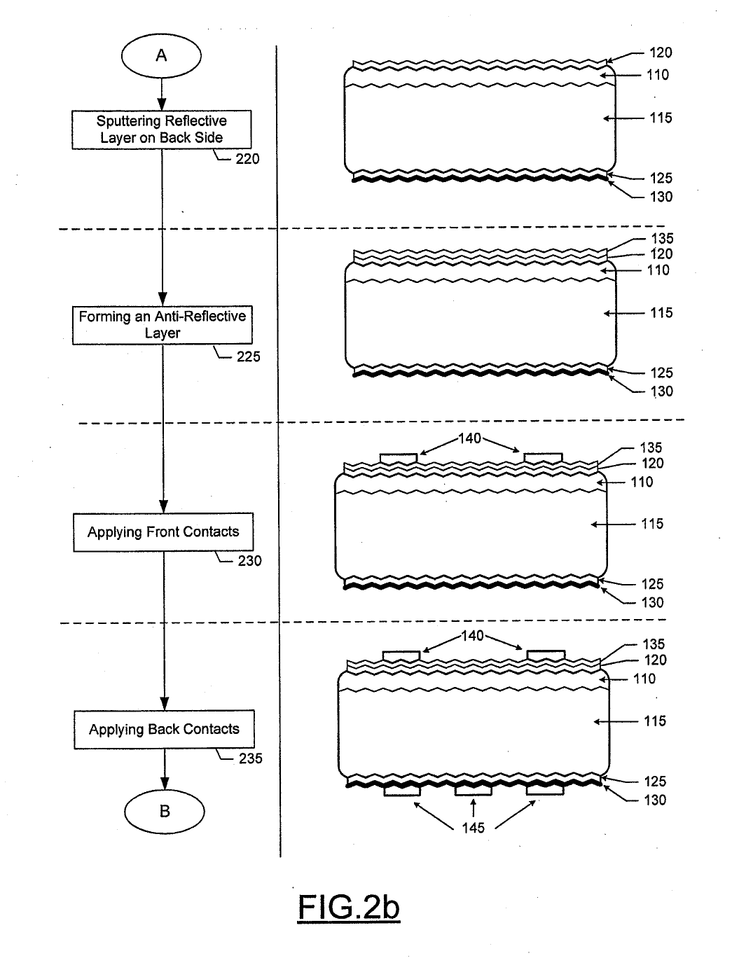

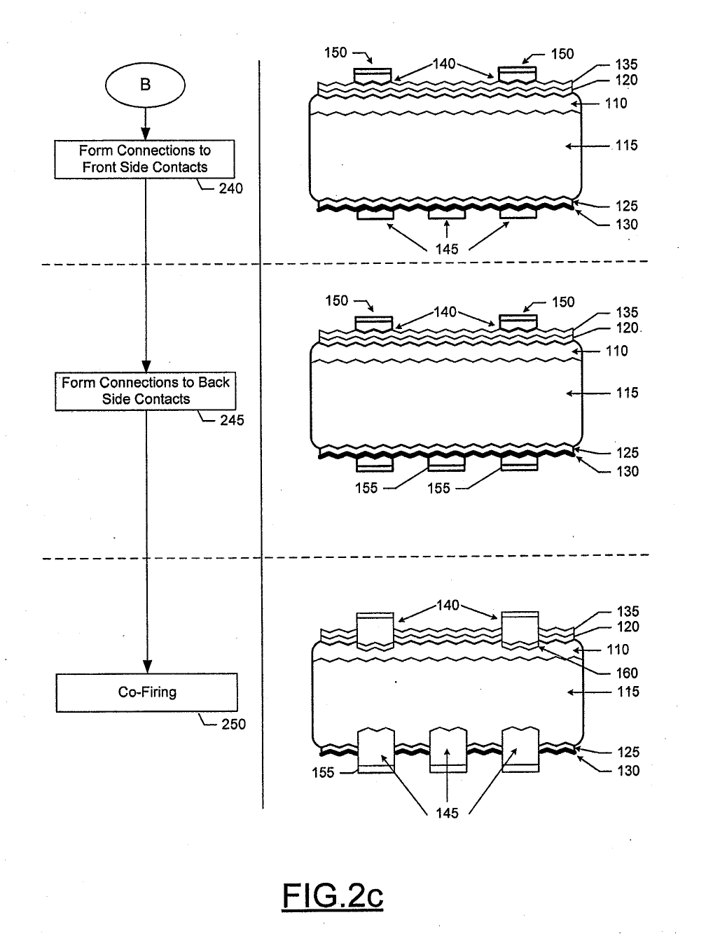

FIGS. 2a-2c illustrate a flowchart according to an exemplary method for manufacturing another exemplary solar cell with a sputtered reflective layer according to an exemplary embodiment of the present invention. FIGS. 2a-2c provide a flowchart on the left, and for each operation, an illustration of the solar cell under construction is depicted to the right of the operation. FIGS. 2a-2c thus disclose exemplary embodiments of the solar cells and methods for their manufacture in accordance with the present invention.

Referring to FIG. 2a, at operation 200 a substrate 100 is provided. The substrate 100 may be as described above with respect to FIG. 1. Specifically, the substrate 100 is composed of a semiconductor material, and it is doped to have a first conductivity type (p-type or n-type). If composed of silicon (Si), germanium (Ge) or silicon-germanium (Si-Ge), the substrate 100 can be doped with boron (B), gallium (Ga), indium (In), aluminum (Al) or possibly another Group III element to produce p-type conductivity. Alternatively, the substrate 100 may be doped with phosphorus (P), antimony (Sb), arsenic (As) or other Group V element to induce n-type conductivity. Normally, a substrate 100 can be ordered from suppliers with a specified amount of p-type or n-type conductivity. The dopant concentration may be in a range from 10¹⁵ to 10²¹ atoms per cubic centimeter (atoms/cm³). The thickness of the substrate 10 can be in a range from 50 to 500 μm, although savings of semiconductor material can be achieved relative to current standard substrates by using substrates with a thickness from 50 to less than 200 μm. Resistivity of the substrate 10 may be in a range from 1 to 100 Ohm-cm, with excellent results obtained using 1 to 3 Ohm-cm. Monocrystalline or multicrystalline, or possibly string ribbon, thin-film or other types of substrates, may be used.

At 200, the substrate 100 is cleaned to prepare it for processing. The cleaning 200 may be accomplished by immersion of the substrate 100 in a bath of potassium hydroxide (KOH) having, for example, about a 1-10% concentration, to etch away saw damage on the surfaces of the substrate 100. According to some example embodiments, etching may be conducted at a temperature from about 60 to 90 degrees Celsius.

At 205, the substrate 100 may be textured. For example, the substrate 100 may be textured by anisotropically etching it by immersion in a bath of potassium hydroxide and isopropyl alcohol (KOH-IPA). According to some example embodiments, the potassium hydroxide concentration may be about a 1-10% concentration, and the isopropyl alcohol may be about a 2-20% concentration. The temperature of the KOH-IPA bath may be about 65 to 90 degrees Celsius. The KOH-IPA etches the surfaces of the substrate 100 to form pyramidal structures 105 with faces at the crystallographic orientation. The resulting pyramidal structures help to reduce reflectivity at the front surface and to trap light within the substrate 100 where it can be absorbed for conversion to electric energy.

At 210, dopant atoms are introduced to the substrate 100. The dopant atoms have a conductivity opposite to that of the substrate 100. Thus, if the substrate 100 has p-type conductivity, then the dopant atoms introduced in operation 210 have n-type conductivity. Conversely, if the substrate 100 has n-type conductivity, then the dopant atoms have p-type conductivity. N-type dopant atoms are generally introduced to the front surface of the substrate 100 (as shown in FIG. 2a) whereas p-type dopants would be introduced to its back surface (not shown). The introduced dopant atoms produce a first region 110 with a first conductivity (p-type or n-type), and the remainder of the substrate 120 constitutes a second region 120 of opposite conductivity (n-type or p-type) to the first region 110. The introduction of dopant atoms may be performed in a number of ways including gas diffusion, ion implantation, spin-on or starved sources.

At 215, for ion-implanted dopants, an annealing operation is undertaken to form the p-n junction 118. The annealing operation 215 can be conducted by heating the substrate 100. The annealing operation 215 may be used to accomplish several objectives at once. First, the annealing 215 drives the introduced dopant atoms deeper into the substrate 100 to form the p-n junction 118. The annealing also repairs damage to the crystalline lattice of the substrate 100 caused by ion implantation if such technique is used to introduce the dopant atoms to the substrate. Moreover, the annealing process may be used to form front and back passivation layers 120, 125 in a single step. The passivation layers 120, 125 may be dielectric oxide layers that protect and passivate respective front and back surfaces of the substrate 100 to reduce occurrence of recombination of charge carriers at the substrate-passivation layer interfaces. Each passivation layer 120, 125 may be formed with a thickness from 10 to 100 nanometers, with 20 nanometers yielding excellent results. To form the passivation layers 120, 125, oxygen (O₂) gas may be introduced to the furnace as the substrate 100 is subjected to an elevated temperature.

Accordingly, the formation of the p-n junction 118 and the generation of the passivation layers 120, 125 may be performed during a single high-temperature operation. Further, by limiting the surface concentration of dopant in the technique used to introduce the dopant atoms, the substrate may be ready for further processing without having to remove a layer of dopant glass that can form when the dopant concentration at the substrate's surface is too high, as may occur if gas diffusion or other technique is used.

Referring now to FIG. 2b, at operation 220, a reflective layer 130 is formed on the back surface of the substrate 100. The reflective layer 130 is formed on the back passivation layer 125. The combination of the reflective layer 130 and the back passivation layer 125 provide a highly reflective structure so that light passing entirely through the substrate 100 reflects back to the substrate to permit another opportunity for its absorption to produce electric energy. The reflective layer 130 may cover the entire back surface of the substrate 100 to prevent leakage of light.

The reflective layer 130 is formed by sputtering to form a thin layer. Sputtering is advantageous because it provides excellent coverage and uniformity in a short period of time, thereby improving throughput for the manufacturing process by reducing the amount of time required to form the reflective layer 130. The layer thickness may be from 0.2 to 1.0 micrometer. According to some exemplary embodiments, the reflective layer 130 may comprise a thin layer of aluminum sputtered on the passivation layer 125 of the back surface of the substrate 100. Several types of sputtering processes may be used in accordance with exemplary embodiments of the present invention, such as ion beam sputtering, diode sputtering, and magnetron sputtering. Sputtering tools that can be used to form the reflective layer 130 include those commercially available from AJA International. The settings for a sputtering tool may be set to a pressure of 3 mTorr, with an Argon flow of 50 sccm, and DC mode power of 500 W.

At 225, an anti-reflective layer 135 may be formed on the passivation layer 120. The anti-reflective layer 135 has a refractive index higher than the underlying passivation layer 120 and thus refracts light into the interior of the substrate 100. The anti-reflective layer 135 may be composed of silicon nitride (Si₃N₄), aluminum oxide (Al₂O₃), titanium oxide (TiO₂), magnesium fluoride (Mg₂F), or zinc sulfide (ZnS₂), or combinations of these materials. The anti-reflective layer 135 may be formed by plasma enhanced chemical vapor deposition (PECVD). Alternatives to the PECVD process may include low pressure chemical vapor deposition (LPCVD), sputtering, and the like. The PECVD process may include heating the substrate 100 to 400 to 450 degrees Celsius. As a by-product of the heating involved in the PECVD process, an “alnealing” process can occur. The alnealing process can reduce water vapor molecules absorbed on the surface of the substrate 100 to hydrogen (H⁺). The water vapor is present at the interface between the substrate 100 and the passivation layers 120, 125 due to the ambient humidity in the manufacturing facility in which the solar cell is manufactured. Most manufacturing facilities are maintained at a humidity range between 40 and 60 percent. The formation of the hydrogen follows from the heating of the aluminum reflective layer 130 during the PECVD process, which in turn radiates sufficient heat to the interface between the substrate 100 and the back passivation layer 120, and possibly also the front passivation layer 125, yet not so much heat as to cause degradation of the interface by overheating which causes increased charge carrier recombination rates. The hydrogen can diffuse to the substrate 100 and passivation layers 120, 125 to passivate them, thereby improving the quality of the interface and reducing the amount of recombination. As a result, according to various exemplary embodiments, a more efficient solar cell is therefore generated via the alnealing process simultaneous with formation of the anti-reflective layer 135.

At 230, the material for the front contacts 120 of the solar cell may be applied to the front surface on the passivation layer 125 on the back surface of the substrate 100. According some exemplary embodiments, the front contacts 140 may be screen-printed using fritted silver paste. The front contacts configuration and spacing are defined by the contact pattern of the screen. In an exemplary embodiment, the contacts can be 50-150 micrometers in width and spaced apart by 1.5-2.5 mm. Alignment of the contact pattern of the screen to the substrate 100 may be accomplished through a variety of techniques known to those of ordinary skill, including butt-edge alignment against two posts, alignment by camera to the center or edge of the substrate 100, or alignment by a fiducial mark formed on the solar cell structure to indicate a position relative to which alignment is to be performed. The silver paste may be self-doping to form heavily-doped regions in the substrate 100 beneath the contacts 145 to facilitate contact with the emitter (region 105) after firing at 245, providing an additional efficiency improvement.

At 235, the material for the back contacts 145 may be applied to the back surface of the solar cell 5 on the reflective layer 115. The back contacts 125 may be formed by dots of fritted aluminum paste. The fitted aluminum paste may be printed with a screen-printing tool. The dots may be sized and spaced to enable current collection in accordance with an acceptable threshold resistance. The spacing and arrangement of point or line contacts can be determined as described in U.S. Publication No. 2009/0025786 published Jan. 29, 2009, which is incorporated by reference as if set forth in full herein. As an example, each of the dots may be about 50-400 micrometers in diameter, and the dots may be spaced approximately 2.4 millimeters apart. According to some exemplary embodiments, the dots may be aligned such that the associated contacts are exposed to incoming light. In this regard, the dots may be offset from the front contacts 140 or their grid line connections next to be described. The solar cell 5 may optionally be placed on a belt furnace at a temperature of 200 to 250 degrees Celsius in air ambient for 30 to 60 seconds to dry the printed paste.

In accordance with some exemplary embodiments, openings may be created for the back contacts 125 prior to firing. In this regard, the openings may be made in the reflective layer 130 and back passivation layer 125 by laser drilling, for example. Alternatively, an etch paste may be used to open contact holes in the reflective layer 130 and passivation layer 125. Suitable etch pastes and techniques for their use are disclosed, for example, in U.S. Publication No. 2009/0025786 published Jan. 29, 2009. Immersion in a bath of dilute hydrofluoric acid, which may have a concentration of about 1-20% and typically about 5%, may be desirable to remove any debris present in the contact holes. In some example embodiments, aluminum may be applied over the openings as a result of the formation of the reflective layer 130 prior to application of the material for the back contacts 125.

Referring now to FIG. 2c, at operation 240, front connections 150 such as grid lines, bus bars or tabs may be formed on the front side of the solar cell 5. As explained previously, these connections 150 can be printed using a screen-printing tool. A fritless, possibly silver, paste may be used to form the connections 150. The connections 150 may be screen-printed on the applied dots for the front contacts 140 using the tool. The paste for the front connections 150 may be subsequently dried with a belt furnace.

At operation 245, back connections 155 such as grid lines, bus bars or tabs are formed on the back side of the solar cell 5. These back connections 155 can be printed using a screen-printing tool. A fritless aluminum paste can be used in operation 245. The back connections 155 may be screen-printed on the applied dots for the back contacts 145, and subsequently dried with a belt furnace.

At operation 250, the substrate 100 with the contacts 140, 145 and connections 150, 155 applied may be heated or co-fired in a belt furnace. In the process of co-firing the structure, the front contacts 140 fire through the anti-reflective layer 135 and the passivation layer 120 to form a physical connection with the front region 110. According to some exemplary embodiments, such as in the case in which a self-doping paste is used, the dopant in the material used for the front contacts 140 may form a region 160 that has a higher carrier concentration remainder of the front region 110. For example, an n⁺⁺ region with a concentration of 10¹⁸ to 10²² atoms per cubic centimeter or higher may be formed directly underneath the front contacts 140.

During the co-firing at 250, the material of the back contacts 125 may fire through the reflective layer 130 and the passivation layer 125 to form a physical contact with the back region 115 of the substrate 100. In addition to providing reflectivity, the reflective layer 130 can also serve as a barrier for preserving the quality of the interface between the passivation layer 125 and the substrate 100 during the co-firing at 250. The connections 155 to the back contacts 145, due to the absence of frit, may remain above the back contacts and the reflective layer 130 during the firing, thereby maintaining the connections between the back contacts 125. The front and back connections 150, 155 also become sintered or soldered to respective front and back contacts 155 so that they are integrally connected and form good electrical connection to respective front and back sides of the solar cell 5. Connections 150, 155 may be adjoined via the tabs and soldered wires to adjacent solar cells in a solar module and ultimately to a load to provide power thereto upon exposure of the front side of the solar cell to light.

According to various exemplary embodiments, and as described above, a solar cell may be formed with a sputtered aluminum reflective layer on the back surface of the solar cell. Many advantages may be realized by forming the reflective layer as described herein. For example, according to various exemplary embodiments, the sputtered aluminum reflective layer operates as a cap to the thermally grown oxide passivation layer and preserves the oxide-to-silicon interface during firing of the contacts. Additionally, according to various exemplary embodiments, the sputtered aluminum reflective layer serves as a high quality reflector having a metal-on-dielectric structure. Moreover, according to various exemplary embodiments, the sputtered aluminum reflective layer provides a source of hydrogen to improve the oxide-to-silicon (passivation-layer-to-substrate) interface by the Alneal process. The manufacture of the solar cell may be greatly simplified by performing multiple steps in a single operation. For example, the dopant atoms may be driven into the substrate to form the p-n junction at the same time the passivation layers are formed. In addition, in a single operation, the anti-reflective layer may be formed as the reflective layer protects and induces formation of hydrogen to passivate the substrate-passivation layer interface. Moreover, all metallization (contacts and connections) can be formed in a single co-firing step. These measures greatly reduce the amount of time, equipment and expense needed to produce the solar cell, and greatly increase the throughput of the manufacturing process.

Many modifications and other embodiments of the inventions set forth herein will come to mind to one skilled in the art to which these inventions pertain having the benefit of the teachings presented in the foregoing descriptions and the associated drawings. Therefore, it is to be understood that the embodiments of the invention are not to be limited to the specific embodiments disclosed and that modifications and other embodiments are intended to be included within the scope of the appended claims. Moreover, although the foregoing descriptions and the associated drawings describe exemplary embodiments in the context of certain exemplary combinations of elements and/or functions, it should be appreciated that different combinations of elements and/or functions may be provided by alternative embodiments without departing from the scope of the appended claims. In this regard, for example, different combinations of steps, elements, and/or materials than those explicitly described above are also contemplated as may be set forth in some of the appended claims. Accordingly, the specification and drawings are to be regarded in an illustrative rather than restrictive sense. Although specific terms are employed herein, they are used in a generic and descriptive sense only and not for purposes of limitation.

What is claimed is:

1. A solar cell comprising:
a crystalline silicon (c-Si or m-Si) substrate having a front region containing dopant atoms of a first conductivity type, and a back region containing dopant atoms of a second conductivity type opposite to the first conductivity type, the silicon substrate defining a p-n junction at the interface between the front region and the back region;
a front passivation layer including silicon dioxide (SiO₂) situated on the front surface of the silicon substrate;
a back passivation layer including silicon dioxide (SiO₂) situated on the back surface of the silicon substrate;
an antireflective layer including silicon nitride (Si₃N₄) situated on the front passivation layer;
a sputtered reflective layer including aluminum (Al) situated on the back passivation layer;
front contacts arranged at spaced locations on the front surface of the solar cell and configured to extend through the antireflective layer and front passivation layer to connect with the front region of the silicon substrate;
back contacts arranged at spaced locations on the back surface of the solar cell and configured to extend through the reflective layer and the back passivation layer to connect with the back region of the silicon substrate;
front connections to connect with the front contacts; and
back connections to connect with the back contacts;
the interfaces between the front passivation layer and the silicon substrate and the back passivation layer and the silicon substrate containing hydrogen to passivate and lower state density at the interfaces.

2. The solar cell of claim 1 wherein the sputtered reflective layer has a thickness of two-tenths (0.2) to one (1.0) micrometer.

3. The solar cell of claim 1 wherein the front contacts include silver (Ag).

4. The solar cell of claim 1 wherein the back contacts include aluminum (Al).

5. The solar cell of claim 1 wherein the front and back connections include silver (Ag).

6. The solar cell of claim 1 wherein the front region of the silicon substrate is n-type and the back region is p-type.

7. A solar cell manufactured by the steps of:
introducing dopant atoms to a front surface of a crystalline silicon substrate;
annealing the substrate to produce a p-n junction with the introduced dopant atoms, and, simultaneous with the annealing, forming front and back passivation layers composed of silicon dioxide (SiO₂), by heating the silicon substrate in an atmosphere containing oxygen (O);
sputtering metal onto the back passivation layer to form a reflective layer; and
forming an antireflective layer on the front passivation layer at a temperature sufficiently elevated to cause the reflective layer to absorb thermal energy to reduce water vapor present at the front and back surfaces of the silicon substrate, thereby producing hydrogen to passivate the interfaces between the front and back passivation layers and the front and back surfaces of the silicon substrate.

8. The solar cell of claim 7 wherein the introducing of the dopant atoms to the front surface of the silicon substrate is performed by ion implantation.

9. The solar cell of claim 7 wherein the introducing of the dopant atoms to the front surface of the silicon substrate is performed by diffusing dopant atoms into the front surface of the silicon substrate.

10. The solar cell of claim 7 wherein the silicon substrate has p-type conductivity and the dopant atoms have n-type conductivity.

11. The solar cell of claim 7 wherein the metal forming the reflective layer comprises aluminum (Al).

12. The solar cell of claim 7 wherein the forming of the antireflective layer is carried out through plasma-enhanced physical vapor deposition (PECVD).

13. The solar cell of claim 7 wherein the antireflective layer includes silicon nitride (Si₃N₄).

14. The solar cell of claim 7 further manufactured by the steps of:
applying front contacts on the antireflective layer;
applying back contacts on the reflective layer;
applying front connections to the front contacts;
applying back connections to the back contacts; and
co-firing the front and back contacts and front and back connections so that the front contacts fire through the front antireflective layer and the front passivation layer to make connection to the front surface of the silicon substrate, and the back contacts fire through the reflective layer and back passivation layer to make connection with the back surface of the silicon substrate, and respective front and back contacts and front and back connections are sintered together to provide electrical connection to the solar cell via the front and back connections.

15. The solar cell of claim 14 wherein the applying of the front contacts includes printing dots of fitted silver paste at front contact locations.

16. The solar cell of claim 14 wherein the applying of the front connections includes printing a fritless silver paste on the front surface of the solar cell to connect to the front contacts.

17. The solar cell of claim 14 wherein the applying of the back contacts includes printing dots of fitted aluminum paste at back contact locations.

18. The solar cell of claim 14 wherein the applying of the back connections includes printing a fritless silver paste on the back surface of the solar cell to connect to the back contacts.

19. The solar cell of claim 14 further manufactured by the step of:
texturing the front and back surfaces of the silicon substrate to form pyramidal structures.
